(19) United States
(12) Patent Application Publication
(10) Pub. No.: US 2016/0072060 A1
(43) Pub. Date: Mar. 10, 2016

(54) MEMORY DEVICE

(71) Applicant: Kabushiki Kaisha Toshiba, Minato-ku (JP)

(72) Inventors: Kikuko SUGIMAE, Kuwana (JP); Kiyohito NISHIHARA, Yokkaichi (JP)

(73) Assignee: Kabushiki Kaisha Toshiba, Minato-ku (JP)

(21) Appl. No.: 14/627,448

(22) Filed: Feb. 20, 2015

Related U.S. Application Data
(60) Provisional application No. 62/048,078, filed on Sep. 9, 2014.

(51) Int. Cl. H01L 45/00

(52) U.S. Cl. CPC H01L 45/122

(57) ABSTRACT

A memory device according to an embodiment, includes a conductive member, a first interconnect, a second interconnect, a first memory element, a first connecting member, a first via and a first contact. The first interconnect is provided on the conductive member. The first interconnect extends in a first direction. The second interconnect is provided on the conductive member above or below the first interconnect. The second interconnect extends in a second direction crossing the first direction. The first memory element is connected between the first interconnect and the second interconnect. The first connecting member is made of the same material as the first interconnect. The first connecting member is separated from the first interconnect. The first via connects the second interconnect to the first connecting member. The first contact connects the first connecting member to the conductive member.

### CROSS-REFERENCE TO RELATED APPLICATIONS

This application is based upon and claims the benefit of priority from U.S. Provisional Patent Application 62/048,078, filed on Sep. 9, 2014; the entire contents of which are incorporated herein by reference.

### FIELD

Embodiments described herein relate generally to a memory device.

### BACKGROUND

In recent years, a resistance random access memory device has been proposed in which data is stored by utilizing the change of an electrical resistance value of a variable resistance film. To efficiently integrate the memory cells, a three-dimensional cross-point structure in which the memory cells are connected between word lines and bit lines has been proposed as the device structure of such a resistance random access memory device. When commercializing the resistance random access memory device, it is desirable to inexpensively manufacture the three-dimensional cross-point structure.

### BRIEF DESCRIPTION OF THE DRAWINGS

FIG. 1 is a plan view showing a memory device according to a first embodiment;

FIG. 2 is a perspective view showing a memory unit of the memory device according to the first embodiment;

FIG. 3 is a plan view showing the memory unit and a periphery of the memory unit of the memory device according to the first embodiment;

FIG. 4 is a plan view showing a bit line draw-out unit of the memory device according to the first embodiment;

FIG. 5 is a cross-sectional view along line A-A′ shown in FIG. 4;

FIG. 6 is a perspective view showing the bit line draw-out unit of the memory device according to the first embodiment;

FIG. 7 is a cross-sectional view showing a bit line draw-out unit of a memory device according to a second embodiment;

FIG. 8 is a cross-sectional view showing a bit line draw-out unit of a memory device according to a third embodiment;

FIG. 9 is a cross-sectional view showing a bit line draw-out unit of a memory device according to a fourth embodiment; and

FIG. 10 is a cross-sectional view showing a bit line draw-out unit of a memory device according to a fifth embodiment.

### DETAILED DESCRIPTION

A memory device according to an embodiment, includes a conductive member, a first interconnect, a second interconnect, a first memory element, a first connecting member, a first via and a first contact. The first interconnect is provided on the conductive member. The first interconnect extends in a first direction. The second interconnect is provided on the conductive member above or below the first interconnect. The second interconnect extends in a second direction crossing the first direction. The first memory element is connected between the first interconnect and the second interconnect. The first connecting member is made of the same material as the first interconnect. The first connecting member is separated from the first interconnect. The first via connects the second interconnect to the first connecting member. The first contact connects the first connecting member to the conductive member.

Embodiments of the invention will now be described with reference to the drawings.

### First Embodiment

First, a first embodiment will be described.

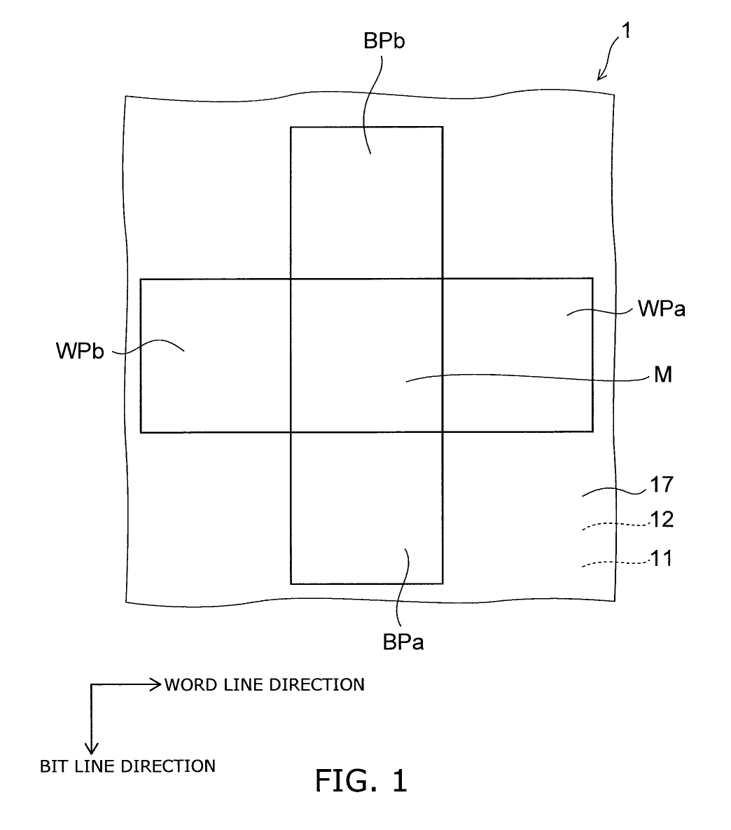

FIG. 1 is a plan view showing a memory device according to the embodiment.

As shown in FIG. 1, a silicon substrate 11 is provided in the memory device 1 according to the embodiment; and a drive circuit (not shown) of the memory device 1 is formed on the upper layer portion and upper surface of the silicon substrate 11. An inter-layer insulating film 12 is provided on the silicon substrate 11 to bury the drive circuit.

For convenience of description hereinbelow, two mutually-orthogonal directions parallel to the upper surface of the silicon substrate 11 are taken as a “word line direction” and a “bit line direction”; and a direction perpendicular to the upper surface of the silicon substrate 11 is taken as a “vertical direction”.

When viewed from the vertical direction, for example, a square memory unit M is provided in the silicon substrate 11; word line draw-out units WPa and WPb are provided at two locations on two word line-direction sides as viewed from the memory unit M; and bit line draw-out units BPa and BPb are provided at two locations on two bit line-direction sides as viewed from the memory unit M.

First, the configuration of the memory unit M will be described.

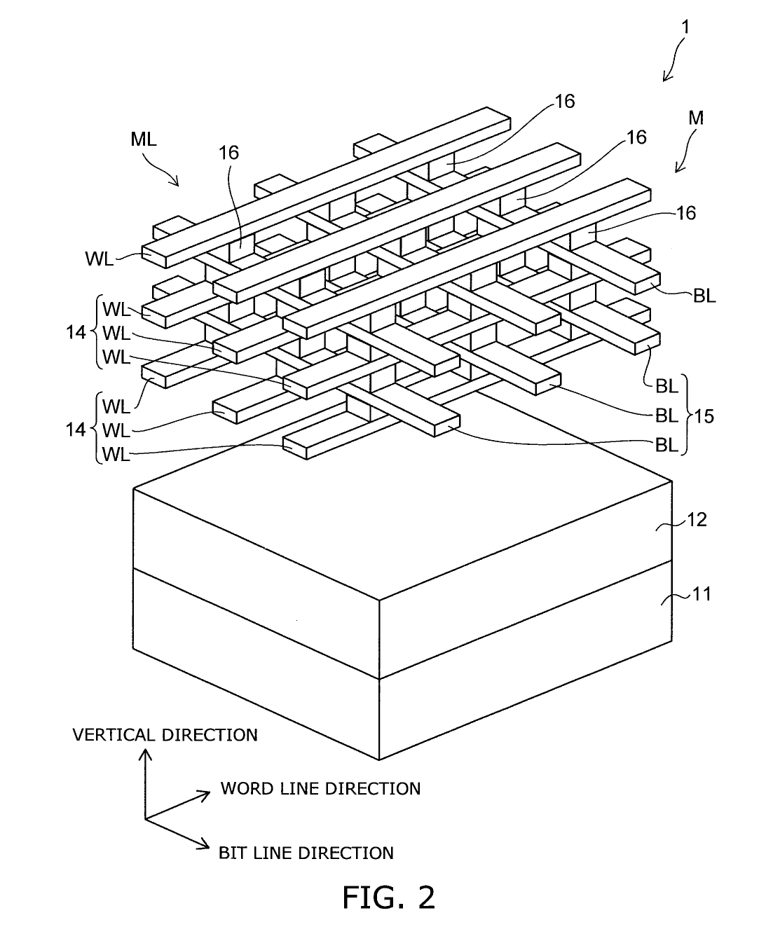

FIG. 2 is a perspective view showing the memory unit of the memory device according to the embodiment.

In the memory unit M of the memory device 1 as shown in FIG. 2, a stacked body ML in which a word line interconnect layer 14 and a bit line interconnect layer 15 are stacked alternately is provided on the inter-layer insulating film 12, where the word line interconnect layer 14 includes multiple word lines WL extending in the word line direction, and the bit line interconnect layer 15 includes multiple bit lines BL extending in the bit line direction. The word lines WL do not contact each other; the bit lines BL do not contact each other; and the word lines WL do not contact the bit lines BL.

Also, a pillar 16 that extends in the vertical direction is provided at the most proximal point between each of the word lines WL and each of the bit lines BL. The pillar 16 is connected between the word line WL and the bit line BL. A variable resistance film (not shown) such as, for example, a metal oxide film, a stacked film of a silicon layer and a silver layer, or the like is provided in the pillar 16. Thereby, the pillar 16 functions as a resistance random access memory element; and one memory cell includes one pillar 16.

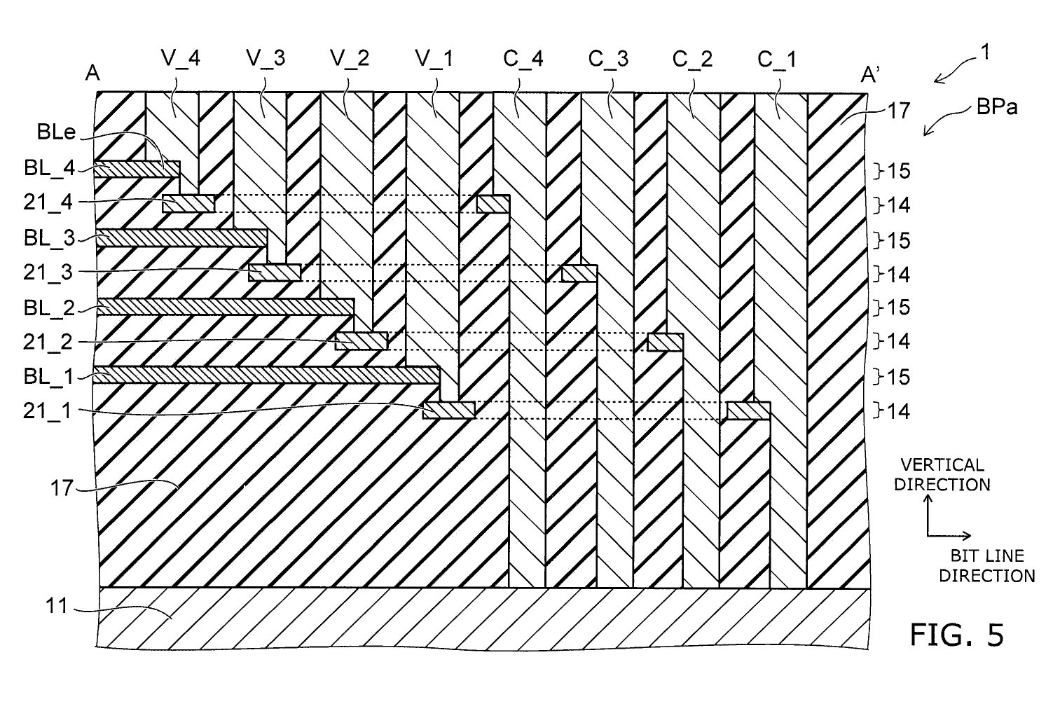

Thus, the memory device 1 is a three-dimensional cross-point device in which memory cells are disposed at each of the most proximal points between the word lines WL and the bit lines BL. The space between the word lines WL, the bit lines BL, and the pillars 16 is filled with an inter-layer insulating film 17 (referring to FIG. 5).

The relationship between the memory unit, the word line draw-out unit, and the bit line draw-out unit will now be described.

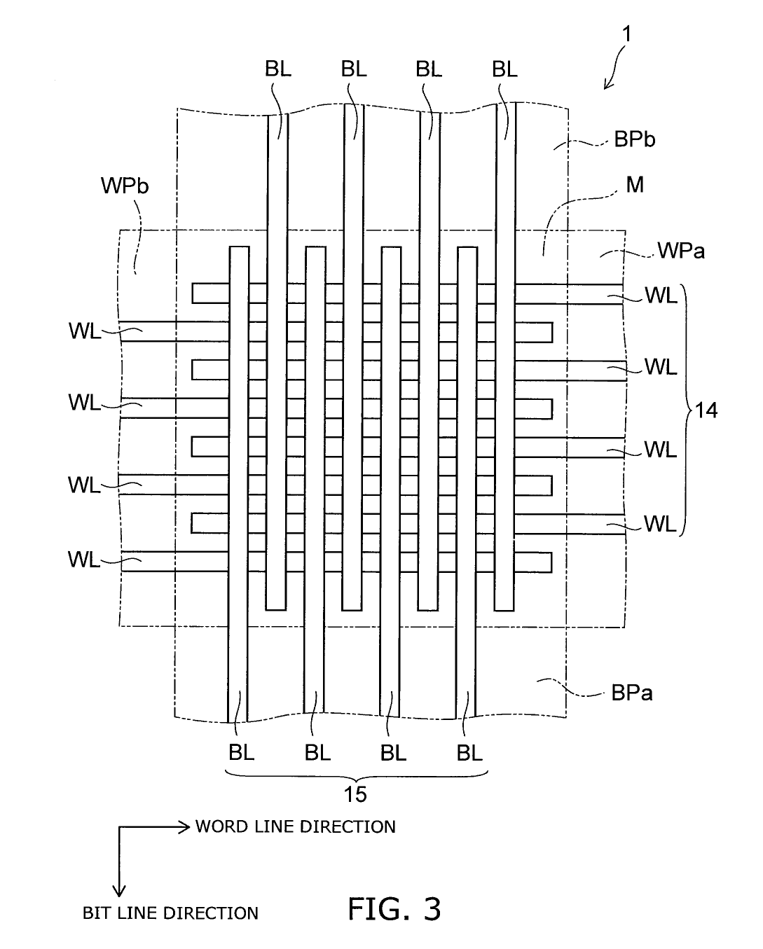

FIG. 3 is a plan view showing the memory unit of the memory device according to the embodiment and the periphery of the memory unit.

As shown in FIG. 3, the word lines WL provided in each of the word line interconnect layers 14 of the memory unit M are drawn out alternately toward the word line draw-out units WPa and WPb disposed at two locations on two sides in the word line direction. In other words, one of two mutually-adjacent word lines WL belonging to the same word line interconnect layer 14 is drawn out to one word line draw-out unit WPa; and the other is drawn out to the word line draw-out unit WPb. Also, the multiple word lines WL that are arranged in the vertical direction are drawn out to the same word line draw-out unit. For example, as viewed from the word line WL drawn out to the word line draw-out unit WPa, all of the word lines WL disposed in the region directly above and the region directly under are drawn out to the word line draw-out unit WPa. Also, the word lines WL that are drawn out to one word line draw-out unit are not drawn out to the other word line draw-out unit and terminate at the boundary vicinity between the memory unit M and the word line draw-out unit.

Similarly, the bit lines BL that are provided in each of the bit line interconnect layers 15 of the memory unit M are drawn out alternately toward the bit line draw-out units BPa and BPb disposed at two locations on two sides in the bit line direction. Also, all of the multiple bit lines BL that are arranged in the vertical direction are drawn out to the same bit line draw-out unit. Also, the bit lines BL that are drawn out to one bit line draw-out unit are not drawn out to the other bit line draw-out unit and terminate at the boundary vicinity between the memory unit M and the bit line draw-out unit.

The bit line draw-out unit will now be described.

Although the bit line draw-out unit BPa is described as an example, the configuration of the bit line draw-out unit BPb also is similar. Also, the configurations of the word line draw-out units WPa and WPb are similar.

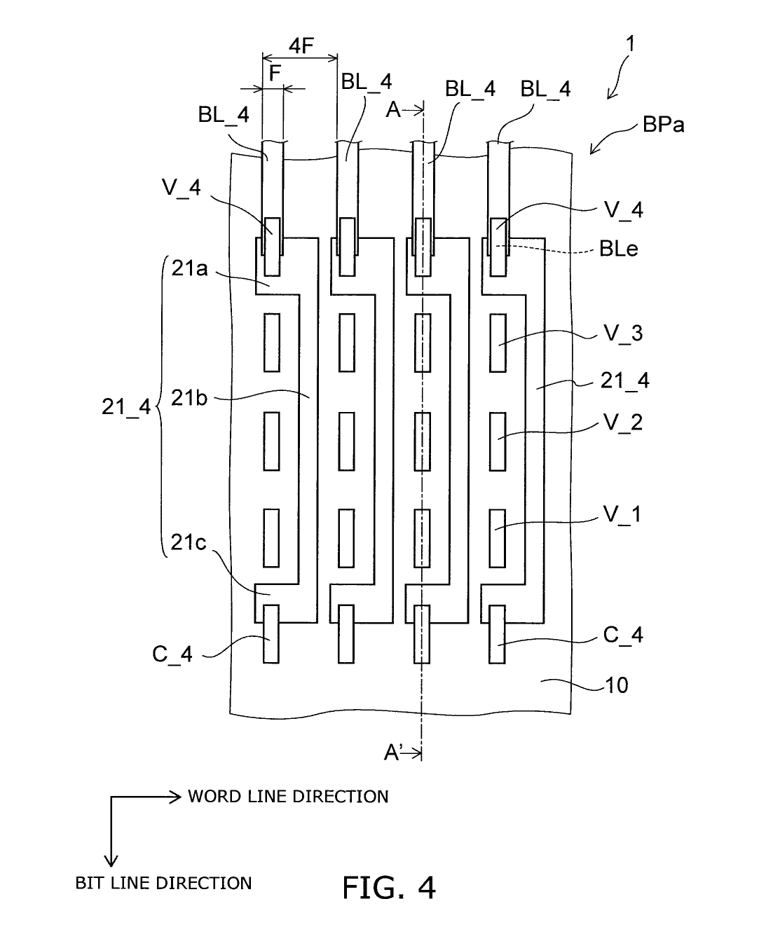

FIG. 4 is a plan view showing the bit line draw-out unit of the memory device according to the embodiment.

FIG. 5 is a cross-sectional view along line A-A′ shown in FIG. 4.

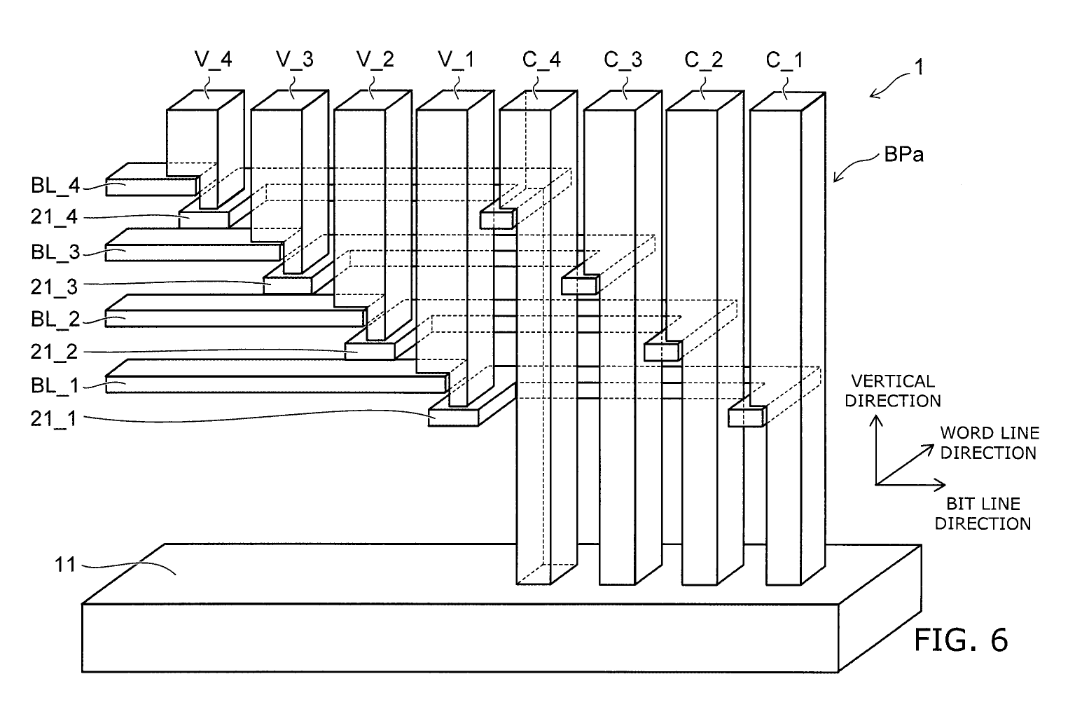

FIG. 6 is a perspective view showing the bit line draw-out unit of the memory device according to the embodiment.

Although an example is illustrated in FIG. 4 to FIG. 6 in which only 4 levels of bit lines BL are arranged along the vertical direction to simplify the drawings, the number of levels of bit lines BL is not limited to 4 levels. Moreover, the inter-layer insulating film 17 is not shown in FIG. 4 and FIG. 6. Further, only the bit lines BL that are arranged in one column along the vertical direction and the members that are connected to the bit lines BL are shown in FIG. 5 and FIG. 6.

As described above, every other bit line BL is drawn out into the bit line draw-out unit BPa. The bit lines BL that are drawn out into the bit line draw-out unit BPa will now be described.

As shown in FIG. 4 to FIG. 6, the bit lines BL that are drawn out into the bit line draw-out unit BPa terminate at prescribed positions inside the bit line draw-out unit BPa. In the bit line direction, the positions of terminal units BLe of the bit lines BL that are drawn out to the bit line draw-out unit BPa and belong to one bit line interconnect layer 15 are the same. Also, the position of the terminal unit BLe becomes more distal to the memory unit M as the bit line BL is disposed at positions more proximal to the silicon substrate 11. The arrangement period of the bit lines BL in the word line direction is 4F, where the width, i.e., the length in the word line direction, of the bit line BL is a minimum patterning dimension F.

In the bit line draw-out unit BPa, one connecting member 21, one via V, and one contact C are provided for each of the bit lines BL. Also, the inter-layer insulating film 17 is provided on the silicon substrate 11 in the bit line draw-out unit BPa. The bit lines BL, the connecting members 21, the vias V, and the contacts C are buried in the inter-layer insulating film 17. The upper ends of the vias V and the contacts C reach the upper surface of the inter-layer insulating film 17 and are at the same position in the vertical direction. In other words, the distances between the silicon substrate 11 and the upper ends of the vias V and the contacts C are equal to each other. In the manufacturing processes of the memory device 1, the upper surface of the inter-layer insulating film 17 is the surface where the lithography for forming the vias V and the contacts C is performed; and in the memory device 1 after the manufacturing, the position of the upper surface of the inter-layer insulating film 17 matches the positions of the upper ends of the vias V and the contacts C. The inter-layer insulating film 17 shown in FIG. 5 includes the inter-layer insulating film 12 (referring to FIG. 2).

Hereinbelow, as necessary, the bit line BL of the first level from the bottom is called the “bit line BL_1”; the bit line BL of the second level is called the “bit line BL_2”; the bit line BL of the third level is called the “bit line BL_3”; and the bit line BL of the fourth level is called the “bit line BL_4”. Similarly for the connecting member 21, the via V, and the contact C as well, the members are differentiated by adding “_k” to the reference numeral of the member of the kth level from the bottom (k being a natural number).

The connecting member 21 is disposed inside the word line interconnect layer 14 one level below as viewed from the bit line interconnect layer 15 in which the bit line BL connected to the connecting member 21 belongs. However, the connecting member 21 is separated from the word lines WL (referring to FIG. 2).

A via connector 21a, an interconnect unit 21b, and a contact connector 21c are provided as one body in the connecting member 21. The interconnect unit 21b is electrically connected (linked) to both the via connector 21a and the contact connector 21c. The via connector 21a and the contact connector 21c are not electrically connected directly but are connected via the interconnect unit 21b. When viewed from the vertical direction, the configuration of the connecting member 21 is a C-shaped configuration. In other words, the widths of the via connector 21a and the contact connector 21c are wider than the width of the bit line BL, e.g., 3F. The width of the interconnect unit 21b is about the same as that of the bit line BL, i.e., F, and extends in the bit line direction. The “width” refers to the length in the word line direction. Also, as viewed from the interconnect unit 21b, the via connector 21a and the contact connector 21c are drawn out toward the same side in the word line direction.

The interconnect unit 21b is electrically connected to one end portion of the via connector 21a in the word line direction and one end portion of the contact connector 21c in the word line direction. Therefore, the interconnect unit 21b is not disposed in the region directly under the bit line BL or the region directly under the space positioned in the bit line direction as viewed from the bit line BL and is shifted in the word line direction by a distance 2F. In other words, in the word line direction, the arrangement period of the interconnect unit 21b is equal to the arrangement period of the bit line BL; and the arrangement of the interconnect units 21b is shifted a one-half period with respect to the arrangement of the bit lines BL.

A portion of the via connector 21a is disposed in the region directly under the terminal unit BLe of the bit line BL. Also, the via V extends downward from above the terminal unit BLe; a portion of the via V contacts the upper surface of the terminal unit BLe; and the remainder passes by the bit line BL on the bit line-direction side and contacts the upper surface of the via connector 21a of the connecting member 21. Thereby, the bit line BL is connected to the connecting member 21 by the via V.

Also, the contact C extends downward from above the contact connector 21c; a portion of the contact C contacts the upper surface of the contact connector 21c; and the remainder passes by the contact connector 21c on the bit line-direction side and contacts, for example, the upper surface of the silicon substrate 11. Thereby, the connecting member 21 is connected to the silicon substrate 11 via the contact C. The contact C is connected to a node of a drive circuit (not shown) formed in the silicon substrate 11. For example, the contact C is connected to the source/drain regions of a selection transistor that switches between whether or not the power supply potential is connected to each of the bit lines BL.

Also, as viewed from the bit line BL, the position of the terminal unit BLe of the bit line BL of one level below is shifted in a direction away from the memory unit M. Accordingly, the positions of the via V, the connecting member 21, and the contact C similarly are shifted.

As described above, the interconnect unit 21b of the connecting member 21 is not disposed in the region directly under the space positioned in the bit line direction as viewed from the bit line BL and is disposed to be shifted from the region directly under the space. Thereby, the interconnect unit 21b does not contact the vias V and the contacts C connected to the bit lines BL of the other levels and detours around these vias V and contacts C. More specifically, the interconnect unit 21b of the connecting member 21 that is connected to one bit line BL passes by on the word line-direction side as viewed from the vias V connected to the bit lines BL of the lower levels and the contacts C connected to the bit lines BL of the upper levels.

In other words, the interconnect unit 21b of the connecting member 21_4 that is connected to the bit line BL_4 of the uppermost level passes by on the word line-direction side as viewed from the vias V_3 to V_1 connected respectively to the bit lines BL_3 to BL_1 of the lower levels. The interconnect unit 21b of the connecting member 21_3 that is connected to the bit line BL_3 of the second level from the top passes by on the word line-direction side as viewed from the vias V_2 and V_1 connected respectively to the bit lines BL_2 and BL_1 of the lower levels and the contact C_4 connected to the bit line BL_4 of the upper level. The interconnect unit 21b of the connecting member 21_2 that is connected to the bit line BL_2 passes by on the word line-direction side as viewed from the via V_1 connected to the bit line BL_1 of the lower level and the contacts C_4 and C_3 connected respectively to the bit lines BL_4 and BL_3 of the upper levels. The interconnect unit 21b of the connecting member 21_1 that is connected to the bit line BL_1 of the lowermost level passes by on the word line-direction side as viewed from the contacts C_4 to C_2 connected to the bit lines BL_4 to BL_2 of the upper levels.

Thus, in the bit line draw-out unit BPa of the embodiment, the contact C is disposed at a position separated from the bit line BL; and each of the bit lines BL is connected to the contact C via the connecting member 21 provided in the word line interconnect layer 14 of one level below the bit line interconnect layer 15 to which the bit line BL belongs. Also, the connecting member 21 detours around the vias V and the contacts C connected to the other bit lines BL and is disposed not to contact these vias V and contacts C. This is similar for the bit line draw-out unit BPb.

This is similar also for the word line draw-out units WPa and WPb. In other words, each of the word lines WL is connected to the contact via a connecting member (not shown) provided in the bit line interconnect layer 15 of one level below the word line interconnect layer 14 to which the word line WL belongs and is connected to the silicon substrate 11 via the contact. For the word line WL of the lowermost level, a dedicated interconnect layer may be provided in which a connecting member for connecting the word line WL to the contact is disposed.

Effects of the embodiment will now be described.

In the embodiment as described above, the bit lines BL belonging to one bit line interconnect layer 15 are connected to the contacts C via the connecting members 21 provided inside the word line interconnect layer 14 one level below. The word lines WL are not provided inside the bit line draw-out units BPa and BPb; and because the bit line draw-out units BPa and BPb are spaces where the word line interconnect layer 14 is available, the connecting members 21 can be routed with high degrees of freedom. Thereby, the connecting member 21 connected to one bit line BL can be disposed to detour around the vias V and the contacts C connected to the other bit lines BL. As a result, all of the vias V and contacts C can be formed from the upper surface of the inter-layer insulating film 17. Accordingly, all of the vias V and contacts C can be formed by performing lithography and etching once. Thereby, the manufacturing cost of the memory device 1 can be reduced.

Also, in the memory unit M, the bit lines BL are formed in a line-and-space configuration at the minimum patterning dimension F. Accordingly, in the bit line draw-out units BPa and BPb as well, the bit lines BL are arranged densely at an arrangement period of 4F. Therefore, in the bit line draw-out units BPa and BPb, it is difficult to pattern the bit lines BL into a configuration other than a line-and-space configuration. Conversely, the word lines WL are not formed in the bit line draw-out units BPa and BPb. Therefore, it is relatively easy to pattern the connecting members 21 into any configuration. Accordingly, according to the embodiment, the manufacturing is easier than in the case where the bit lines BL themselves are patterned into a complex configuration to detour around the vias V and the contacts C.

Further, because the connecting members 21 can be formed simultaneously with the word lines WL from the same material, it is unnecessary to add a dedicated process for forming the connecting members 21. Each of the word line interconnect layers 14 can be formed by simultaneously forming the word lines WL and the connecting members 21, subsequently burying the word lines WL and the connecting members 21 with an inter-layer insulating film, and by performing chemical mechanical polishing (CMP) of the upper surface. Also, according to the embodiment, because the connecting members 21 are disposed in the word line interconnect layer 14 in the bit line draw-out units BPa and BPb, the connecting members 21 are used as the stopper of the CMP; and the CMP of the upper surface of the word line interconnect layer 14 can be performed uniformly.

Further, the bit line BL and the connecting member 21 that overlap as viewed from the vertical direction are shorted by the via V. Accordingly, even in the case where a memory cell parasitically occurs in the portion where the bit line BL and the connecting member 21 overlap, the effects on the circuit operation can be suppressed.

The effects described above are similar also for the word line draw-out units WPa and WPb.

Although an example is illustrated in the embodiment in which the contacts C are disposed in the bit line direction as viewed from the bit lines BL, this is not limited thereto. The contacts C can be provided in unused space because the connecting members 21 can be routed freely. For example, the contacts C may be disposed in a rectangular region that has two sides contacting the word line draw-out unit WPa and the bit line draw-out unit BPa shown in FIG. 1. Thereby, because the dead space can be utilized effectively, the memory device can be downsized. Also, because the connecting members 21 can be disposed in the rectangular region described above, CMP of the word line interconnect layer 14 becomes more uniform.

### Second Embodiment

A second embodiment will now be described.

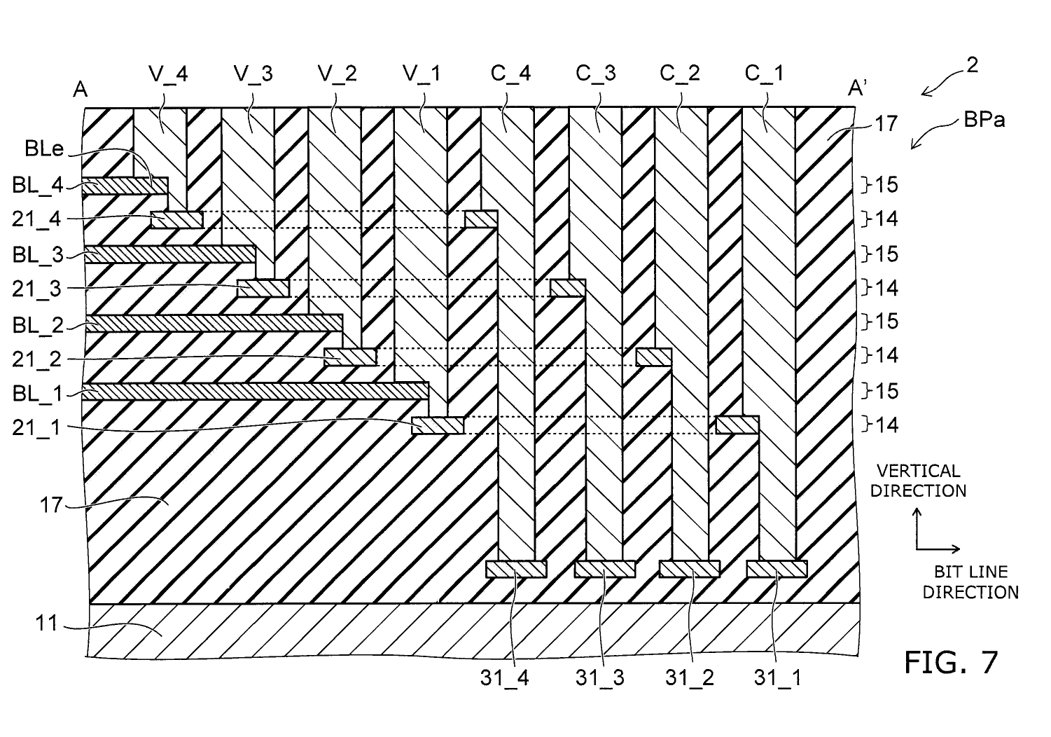

FIG. 7 is a cross-sectional view showing the bit line draw-out unit of a memory device according to the embodiment.

As shown in FIG. 7, the memory device 2 according to the embodiment differs from the memory device 1 according to the first embodiment described above (referring to FIG. 5) in that the contacts C are connected not to the silicon substrate 11 but to lower layer interconnects 31. Specifically, the lower ends of contacts C_4, C_3, C_2, and C_1 respectively contact the upper surfaces of a lower layer interconnect 31_4, a lower layer interconnect 31_3, a lower layer interconnect 31_2, and a lower layer interconnect 31_1.

According to the embodiment, because the lower layer interconnects 31 can be routed between the drive circuit and the contacts C, the degrees of freedom of the arrangement positions of the contacts C and the layout of the drive circuit are high. Otherwise, the configuration and the effects of the embodiment are similar to those of the first embodiment described above.

Some of the contacts C may be connected to the lower layer interconnects 31; and the remaining contacts C may be connected to the silicon substrate 11. Also, the contacts C may be connected to the gate electrodes of field effect transistors formed in the silicon substrate 11. In other words, it is sufficient for the lower ends of the contacts C to be connected to any conductive member. In such a case, the conductive member includes the silicon substrate 11, the lower layer interconnects 31, and the gate electrodes but is not limited thereto.

### Third Embodiment

A third embodiment will now be described.

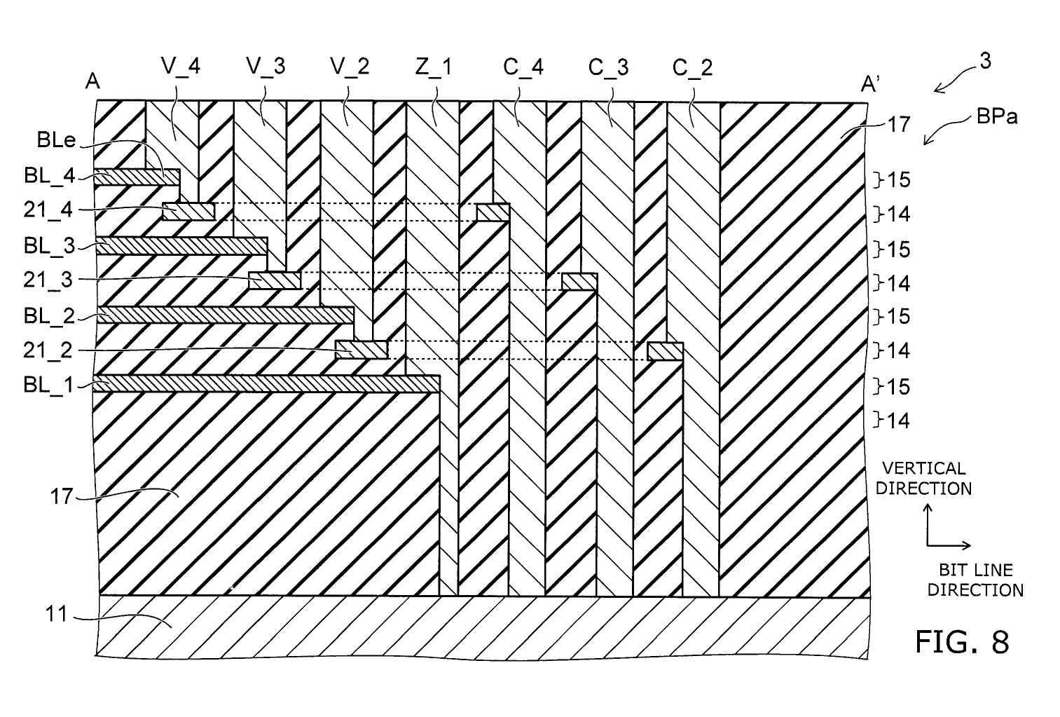

FIG. 8 is a cross-sectional view showing the bit line draw-out unit of a memory device according to the embodiment.

In the memory device 3 according to the embodiment as shown in FIG. 8, a contact Z_1 is provided instead of the via V_1 connected to the bit line BL_1 of the lowermost layer. The middle portion of the contact Z_1 in the vertical direction contacts the bit line BL_1; and the lower end contacts the silicon substrate 11. Thereby, the bit line BL_1 is connected to the silicon substrate 11 via the contact Z_1. On the other hand, in the memory device 3, the connecting member 21_1 and the contact C_1 (referring to FIG. 5) are not provided.

According to the embodiment, compared to the memory device 1 according to the first embodiment described above (referring to FIG. 5), the length of the bit line draw-out unit BPa in the bit line direction can be reduced. Otherwise, the configuration and the effects of the embodiment are similar to those of the first embodiment described above.

### Fourth Embodiment

A fourth embodiment will now be described.

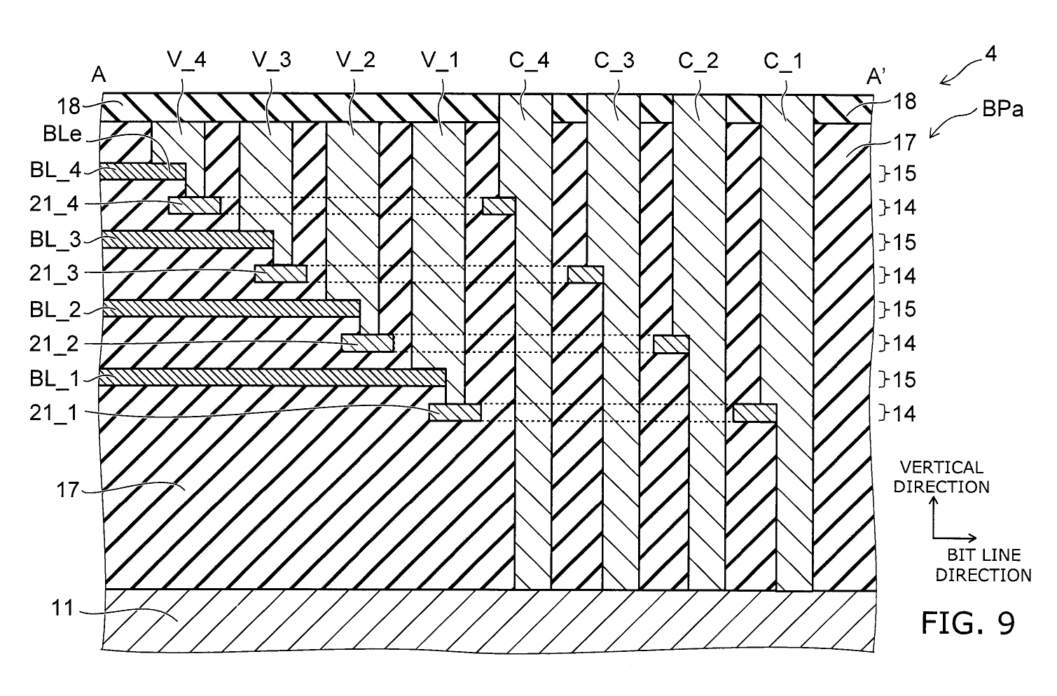

FIG. 9 is a cross-sectional view showing the bit line draw-out unit of a memory device according to the embodiment.

In the memory device 4 according to the embodiment as shown in FIG. 9, the positions of the upper ends of the contacts C in the vertical direction are higher than the positions of the upper ends of the vias V. In the vertical direction, the positions of the upper ends of the vias V_1 to V_4 are equal to each other; and the positions of the upper ends of the contacts C_1 to C_4 are equal to each other.

More specifically, an inter-layer insulating film 18 is provided on the inter-layer insulating film 17; the upper ends of the vias V_1 to V_4 are in the same plane as the upper surface of the inter-layer insulating film 17; and the upper ends of the contacts C_1 to C_4 are in the same plane as the upper surface of the inter-layer insulating film 18.

Such a structure is realized in the case where, for example, the vias V are formed by performing lithography after forming the inter-layer insulating film 17; and subsequently, the inter-layer insulating film 18 is formed on the inter-layer insulating film 17, and the contacts C are formed by performing lithography.

Otherwise, the configuration and the effects of the embodiment are similar to those of the first embodiment described above.

The upper ends of the contacts C may be in the same plane as the upper surface of the inter-layer insulating film 17; and the upper ends of the vias V may be in the same plane as the upper surface of the inter-layer insulating film 18. Also, the vias V may be connected to upper layer interconnects provided inside the inter-layer insulating film 18.

### Fifth Embodiment

A fifth embodiment will now be described.

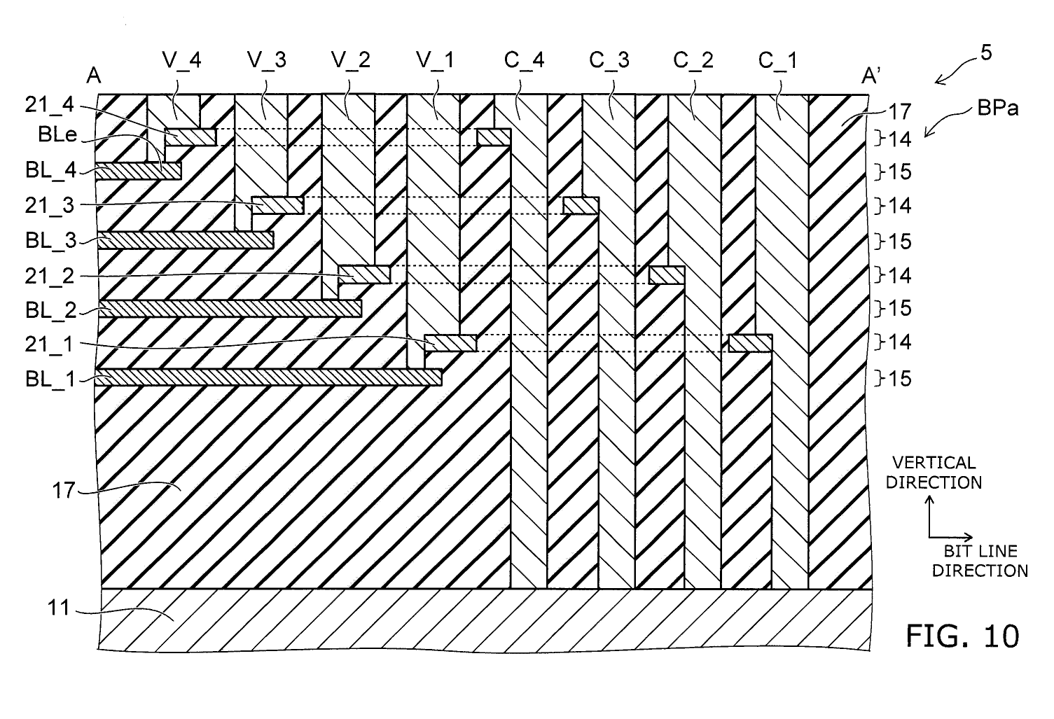

FIG. 10 is a cross-sectional view showing the bit line draw-out unit of a memory device according to the embodiment.

As shown in FIG. 10, the memory device 5 according to the embodiment differs from the memory device 1 according to the first embodiment described above (referring to FIG. 5) in that the connecting members 21 are disposed higher than the bit lines BL connected to the connecting members 21. For example, the connecting member 21_3 that is connected to the bit line BL_3 is provided inside the word line interconnect layer 14 disposed between the bit line interconnect layer 15 to which the bit line BL_3 belongs and the bit line interconnect layer 15 to which the bit line BL_4 belongs.

Thereby, effects similar to those of the first embodiment described above can be obtained. Otherwise, the configuration and the effects of the embodiment are similar to those of the first embodiment described above.

According to the embodiments described above, a memory device that can be manufactured inexpensively can be realized.

The device according to the invention is not limited a memory device, may also be a device other than a memory device. For example, the device according to the invention may be a MEMS (micro-electro mechanical system).

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention. Additionally, the embodiments described above can be combined mutually.

What is claimed is:

1. A memory device, comprising:
a conductive member;
a first interconnect provided on the conductive member, the first interconnect extending in a first direction;
a second interconnect provided on the conductive member above or below the first interconnect, the second interconnect extending in a second direction crossing the first direction;
a first memory element connected between the first interconnect and the second interconnect;
a first connecting member of the same material as the first interconnect, the first connecting member being separated from the first interconnect;
a first via connecting the second interconnect to the first connecting member; and
a first contact connecting the first connecting member to the conductive member.

2. The memory device according to claim 1, wherein
the first connecting member includes:
a first portion, the first via contacting an upper surface of the first portion;
a second portion electrically connected to the first portion and disposed in a region other than a region directly under the second interconnect, other than a region directly above the second interconnect, other than a region directly under a space, and other than a region directly above the space, the space being positioned in the second direction as viewed from the second interconnect; and
a third portion electrically connected to the second portion, the first contact contacting an upper surface of the third portion.

3. The memory device according to claim 1, further comprising:
a third interconnect provided on the second interconnect, the third interconnect extending in the first direction;
a fourth interconnect provided on the third interconnect, the fourth interconnect extending in the second direction;
a second memory element connected between the third interconnect and the fourth interconnect;
a second connecting member of the same material as the third interconnect, the second connecting member being separated from the third interconnect;
a second via connecting the fourth interconnect to the second connecting member; and
a second contact connecting the second connecting member to the conductive member,
the second interconnect being disposed on the first interconnect,
the second connecting member being separated from the first via.

4. The memory device according to claim 3, wherein an upper end of the first via and an upper end of the second via are at the same position in a direction in which the first contact extends.

5. The memory device according to claim 3, wherein an upper end of the first contact and an upper end of the second contact are at the same position in a direction in which the first contact extends.

6. The memory device according to claim 3, wherein an upper end of the first via, an upper end of the second via, an upper end of the first contact, and an upper end of the second contact are at the same position in a direction in which the first contact extends.

7. The memory device according to claim 3, wherein
the second connecting member includes:
a first portion, the second via contacting an upper surface of the first portion;
a second portion electrically connected to the first portion, the second portion passing by on the first-direction side as viewed from the first via; and
a third portion electrically connected to the second portion, the second contact contacting an upper surface of the third portion.

8. The memory device according to claim 3, wherein
the first connecting member includes:
a first portion, the first via contacting an upper surface of the first portion;
a second portion electrically connected to the first portion, the second portion passing by on the first-direction side as viewed from the second contact; and
a third portion electrically connected to the second portion, the first contact contacting an upper surface of the third portion.

9. The memory device according to claim 3, wherein
the first connecting member includes:
a first portion, the first via contacting an upper surface of the first portion;
a second portion electrically connected to the first portion, the second portion passing by on the first-direction side as viewed from the second contact; and
a third portion electrically connected to the second portion, the first contact contacting an upper surface of the third portion, and
the second connecting member includes:
a fourth portion, the second via contacting an upper surface of the fourth portion;
a fifth portion electrically connected to the fourth portion, the fifth portion passing by on the first-direction side as viewed from the first via; and
a sixth portion electrically connected to the fifth portion, the second contact contacting an upper surface of the sixth portion.

10. The memory device according to claim 3, further comprising:
a third connecting member of the same material as the second interconnect, the third connecting member being separated from the second interconnect;
a third via connecting the third interconnect to the third connecting member; and
a third contact connecting the third connecting member to the conductive member.

11. The memory device according to claim 1, wherein the conductive member is a semiconductor substrate.

12. The memory device according to claim 1, further comprising a semiconductor substrate,
the conductive member being an interconnect,
the interconnect being disposed between the semiconductor substrate and the first contact.

13. The memory device according to claim 1, further comprising:
a third interconnect provided on the first interconnect, the third interconnect extending in the second direction;
a fourth interconnect provided on the third interconnect, the fourth interconnect extending in the first direction;
a second memory element connected between the third interconnect and the fourth interconnect;
a second connecting member of the same material as the fourth interconnect, the second connecting member being separated from the fourth interconnect;
a second via connecting the third interconnect to the second connecting member; and
a second contact connecting the second connecting member to the conductive member,
the first interconnect being disposed on the second interconnect,
the second connecting member being separated from the first via.

14. The memory device according to claim 13, wherein an upper end of the first via, an upper end of the second via, an upper end of the first contact, and an upper end of the second contact are at the same position in a direction in which the first contact extends.

15. The memory device according to claim 13, wherein
the first connecting member includes:
a first portion, the first via contacting an upper surface of the first portion;
a second portion electrically connected to the first portion, the second portion passing by on the first-direction side as viewed from the second contact; and
a third portion electrically connected to the second portion, the first contact contacting an upper surface of the third portion, and
the second connecting member includes:
a fourth portion, the second via contacting an upper surface of the fourth portion;
a fifth portion electrically connected to the fourth portion, the fifth portion passing by on the first-direction side as viewed from the first via; and
a sixth portion electrically connected to the fifth portion, the second contact contacting an upper surface of the sixth portion.

16. A memory device, comprising:
a conductive member;
a first interconnect layer provided on the conductive member, the first interconnect layer including a first connecting member and a plurality of first interconnects, the plurality of first interconnects extending in a first direction;
a second interconnect layer provided on the first interconnect layer, the second interconnect layer including a plurality of second interconnects extending in a second direction crossing the first direction;
a third interconnect layer provided on the second interconnect layer, the third interconnect layer including a second connecting member and a plurality of third interconnects, the plurality of third interconnects extending in the first direction;
a fourth interconnect layer provided on the third interconnect layer, the fourth interconnect layer including a plurality of fourth interconnects extending in the second direction;
a first memory element connected between the first interconnect and the second interconnect;
a second memory element connected between the third interconnect and the fourth interconnect;
a first via connecting the second interconnect to the first connecting member;
a first contact connecting the first connecting member to the conductive member;
a second via connecting the fourth interconnect to the second connecting member; and
a second contact connecting the second connecting member to the conductive member,
the first connecting member being separated from the second contact,
the second connecting member being separated from the first via.

17. The memory device according to claim 16, wherein
the second interconnect layer further includes a third connecting member, and
the memory device further comprises:
a third via connecting the third interconnect to the third connecting member; and
a third contact connecting the third connecting member to the conductive member.

18. The memory device according to claim 16, wherein an upper end of the first via, an upper end of the second via, an upper end of the first contact, and an upper end of the second contact are at the same position in a direction in which the first contact extends.

19. A device, comprising:
a conductive member;
a first interconnect provided on the conductive member, the first interconnect extending in a first direction;
a second interconnect provided on the conductive member above or below the first interconnect, the second interconnect extending in a second direction crossing the first direction;
a first connecting member of the same material as the first interconnect, the first connecting member being separated from the first interconnect;
a first via connecting the second interconnect to the first connecting member; and
a first contact connecting the first connecting member to the conductive member.

20. The device according to claim 19, further comprising:
a third interconnect provided on the second interconnect, the third interconnect extending in the first direction;
a fourth interconnect provided on the third interconnect, the fourth interconnect extending in the second direction;
a second connecting member of the same material as the third interconnect, the second connecting member being separated from the third interconnect;
a second via connecting the fourth interconnect to the second connecting member; and
a second contact connecting the second connecting member to the conductive member,
the second interconnect being disposed on the first interconnect,
the second connecting member being separated from the first via.
